(19) United States
(12) Patent Application Publication
(10) Pub. No.: US 2013/0209704 A1
(43) Pub. Date: Aug. 15, 2013

(54) POWER LANCE AND PLASMA-ENHANCED COATING WITH HIGH FREQUENCY COUPLING

(71) Applicant: KRONES AG, (US)

(72) Inventors: Jochen Krueger, Hagelstadt (DE); Andreas Sonnauer, Worth (DE); Roland Gesche, Selingenstadt (DE)

(73) Assignee: KRONES AG, Neutraubling (DE)

(21) Appl. No.: 13/752,583

(22) Filed: Jan. 29, 2013

(30) Foreign Application Priority Data
Feb. 9, 2012 (DE) DE 102012201955.3

(51) Int. Cl. C23C 16/455

(52) U.S. Cl. CPC C23C 16/455
USPC 427/569; 118/723 R

(57) ABSTRACT

The disclosure relates to an apparatus for coating a container e.g. a plastic bottle, by means of a plasma treatment. The apparatus includes a high-frequency source, an outer electrode located outside the container to be treated, and an at least partially electrically conducting gas lance for the supply of process gas into the container. The outer electrode is grounded and/or is on the same potential as other parts of the container coating apparatus located outside the container to be treated, such as pressure chamber parts or housing parts. The at least one gas lance is capable of irradiating a high frequency, which can be generated by the high-frequency source, into the interior of the container to be treated.

### BACKGROUND

In order to reduce the permeability of container walls/walls of hollow bodies it is advantageous to provide them with a barrier layer, e.g. by means of plasma-enhanced chemical vapor deposition (PECVD) as is described, for instance, in EP 0881197A2.

For the coating of containers by means of a plasma treatment, e.g. the interior plasma coating of plastic bottles, a so-called high-frequency plasma may, inter alia, be used.

In this context, for instance, a plasma is generated in a bottle by evacuating the interior of the bottle to a pressure in the range of 1-10 Pa and exposing it to a high-frequency field. By means of gas lance it is possible to introduce a gas mixture, for instance consisting of a silicon monomer and oxygen, into the interior of the bottle. This gas flow allows the pressure inside the bottle to increase by some 10 Pa so that it can be in the range of 10-30 Pa or more.

A flat electrode may be located outside the bottle, which can be supplied with high frequency, e.g. 13.56 MHz. The gas lance, which simultaneously also acts as an electrode, is usually made of metal and is grounded by a connection to the machine housing as is described, for instance, in WO2009026869.

The high frequency couples to the gas lance, and a plasma can be ignited inside the bottle. The process gas may be uniformly distributed in the bottle through a plurality of suitably positioned bores in the gas lance, thus obtaining a uniform coating inside the bottle.

However, this kind of high-frequency coupling is not suited for the coating of large surfaces, e.g. the inside of bottles, at high deposition rates of more than >2 nm/s, as this requires a high gas flow and, as a consequence, a high electrical power in the form of high frequency. Due to the electric network, in particular the capacitive coupling of the high frequency between the electrode and the bottle, the high power entails very high electric potentials on the electrode. As the surroundings of the electrode, in particular metallic parts in the region of the bottle opening (e.g. valve, bottle clamp, gas lance) have to be grounded,

the high frequency keeps producing undesired electric discharges outside the bottles or inside the container coating apparatus causing damages to the bottle and/or the container coating apparatus.

Moreover, these undesired electric discharges, which may also be called parasitic discharges, reduce the electric power available for the plasma-enhanced coating of the container, which may lead to an inferior or insufficient coating quality. In addition, parasitic discharges may result in a maladjustment of the matchbox in the impedance network.

Therefore, it is an object of the present disclosure to improve an apparatus for coating containers by means of a plasma treatment, for instance the plasma-enhanced coating of plastic bottles, in particular with regard to reliability and efficiency.

SUMMARY

According to some aspects of the disclosure, this is achieved by an apparatus according to claim 1 and a method according to claim 13. Advantageous embodiments and further developments are described in the dependent claims.

An apparatus according to one or more aspects of the disclosure for the plasma-enhanced coating of a container may include at least one high-frequency source, at least one outer electrode located outside the container to be treated, and at least one at least partially electrically conducting gas lance for the supply of process gas into the container. The outer electrode may be grounded and/or be on the same potential as other parts of the container coating apparatus located outside the container to be treated, for instance pressure chamber parts or housing parts. The gas lance is capable of irradiating a high frequency, which can be generated by the high-frequency source, into the interior of the container to be treated. For the deposition of quartz-like layers the process gas used may be, for instance, a mixture of oxygen and a gaseous silicon-organic monomer such as hexamethyldisiloxane (HMDSO), HMDSN, TEOS, TMOS, HMCTSO, APTMS, SiH4, TMS, OMCTS or comparable compounds. Analogously, C2H2, C2H4, CH4, C6H6 or other carbon-containing source substances may be used for the deposition of carbon-containing layers (diamond-like carbon “DLC”).

In a method for the plasma-enhanced coating of a container according to some aspects of the disclosure the container B to be treated may then be supplied by an ungrounded gas lance PL with process gas and with a high frequency HF coupled to a grounded outer electrode AE located outside the container B. The process gas can then ignite inside the container and be converted in whole or in part into a plasma, and the interior of the container B can be coated by means of a chemical vapor deposition.

In some arrangements, the container coating apparatus as described as well as the method as described have the advantage that, for instance, no plasma between the outer electrode and parts of the container coating apparatus, such as pressure chamber parts of housing parts, is ignited by undesired discharges, as the outer electrode and said parts are on the same potential, e.g. on ground potential.

The gas lance extending into the container to be treated may be electrically shielded, at least in part coaxially. The electrical coaxial shielding may end inside the container.

This optional coaxial shielding of the gas lance has the advantage, for instance, that the irradiation area of the high frequency is easier to control and bound, e.g. for the selective irradiation of the high frequency into the interior, e.g. into the center or, preferably, into the lower two thirds of the container to be treated.

The gas lance may be made of a material which may be both permeable to process gas and electrically conducting, for instance, like a metal tube or a porous metallic foam.

The gas lance may also be configured to allow the supply of process gas and the supply or conduction of the high frequency to be physically separated. To this end, the part of the gas lance conducting the high frequency is electrically conducting. The part of the gas lance supplying the process gas may be made either in part or in whole of an electrically non-conducting material, e.g. a synthetic material or ceramics, in part or in whole of an electrically conducting material, or of a combination of an electrically conducting and non-conducting material.

In addition, the gas lance may include a plurality of preferably lateral gas inlet bores for distributing the process gas uniformly in the container. Thus, a uniform coating of the interior of the container can be facilitated.

It is possible, however, that process gas streaming out of the gas lance ignites through the gas inlet bores, e.g. as a result of possible undesired discharges on or inside the gas lance, and generates an electrically conducting connection in the form of a plasma into the interior of the gas lance, where a so-called hollow body plasma/hollow cathode plasma can be established.

In order to avoid such undesired discharges inside the gas lance, the gas lance may advantageously include, for instance, a plurality of gas inlet bores having bore diameters smaller than 0.1, 0.2 or 0.5 mm and bore lengths of 0.1-10 mm, or the gas lance is made of an open-pored metal foam or sintered metal having pore diameters in the range of <10-100 μm. Open-pored ceramic foams, e.g. of aluminum oxide or other oxide ceramics, are conceivable as well.

This has the advantage that charge carriers can no longer be accelerated in a straight line to reach energies which, upon a subsequent collision, can lead to an ionization of the collision partner in the gas. Thus, gas discharges inside the gas lance can be avoided or reduced, respectively.

The figures illustrate by way of examples:

### BRIEF DESCRIPTION OF THE DRAWINGS

FIG. 1 is a schematic example of an apparatus for the plasma-enhanced coating of a container.

FIG. 2a shows an example gas lance.

FIG. 2b shows an example gas lance.

FIG. 3a shows an example gas lance.

FIG. 3b shows an example gas lance.

FIG. 4a shows an example gas lance.

FIG. 4b shows an example gas lance.

FIG. 5 shows an example gas lance.

FIG. 6 shows an example gas lance.

FIG. 7a shows an example gas lance in the magnetic field.

FIG. 7b shows an example gas lance in the magnetic field.

### DETAILED DESCRIPTION

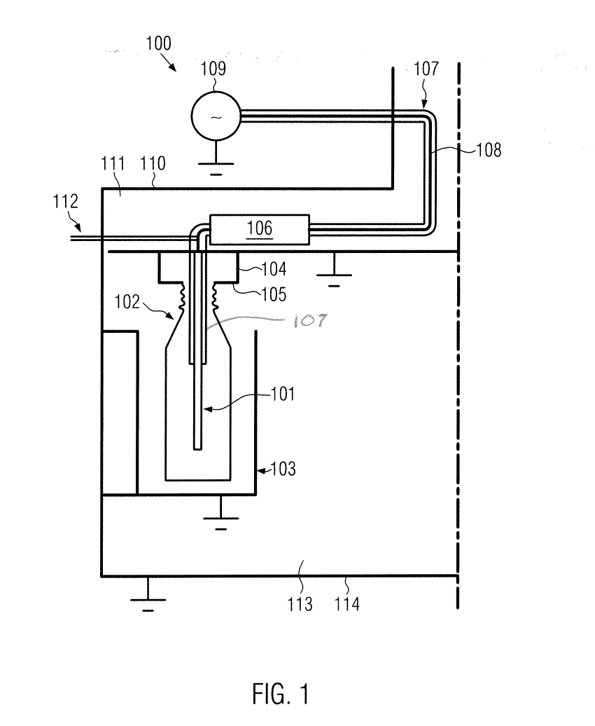

FIG. 1 shows by way of example an apparatus 100 for the plasma-enhanced coating of a container 102. The apparatus 100 may have two different pressure areas, e.g. a basic pressure chamber 113 which can be evacuated, for instance, to pressures of 100 to 4000 Pa, and for instance a process pressure chamber 111 in which, for instance, pressures between 1 to 30 Pa may be present. A high-frequency source 109 may feed high frequency through a coaxial cable 108 into a gas lance 101. Optionally, the efficiency of the power transfer between the high-frequency source 109 and the gas lance 101 can be optimized by means of a power matcher 106 by what is called radio frequency matching. The coaxial cable 108 may be electrically shielded. Also, the gas lance 101 may be electrically shielded, at least in part, and comprise, for instance, a coaxial shielding 107 which, if a gas lance 101 is introduced into the container 102, may extend into the interior of the container or up to the end of the gas lance 101, preferably only until the last two thirds of the gas lance 101, however.

By means of an electrical shielding 107 of the gas lance 101 in part it is possible to achieve a more selective irradiation of the high frequency into the interior of the container 102 and, for instance, undesired gas discharges in the region of the container opening/bottle opening at metallic parts, such as valve 104, bottle clamp 105 etc., may be reduced or avoided. The basic pressure chamber 113 may comprise an outer electrode 103, e.g a U-shaped one, which can enclose the container 102 to be treated at least in part without contacting the container 102, as the container may be suspended, for instance, by a bottle clamp 105. The outer electrode 103 may be connected, for instance, electrically to a part of the basic pressure chamber housing 114 and may thus, for instance, be grounded.

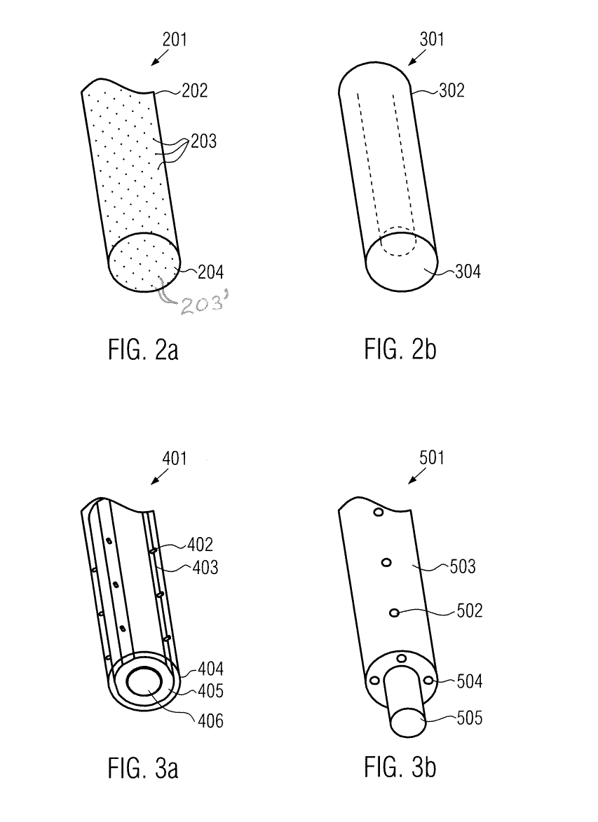

FIG. 2a shows an example of a gas lance 201, which may be made of a material that may be both electrically conducting and capable of conducting the high frequency and, at the same time, capable of supplying the process gas. To this end, the gas lance 201 may be a metal tube 202 which may include, for instance, a plurality of bores 203, e.g. 1 to 10 or more bores per cm2, which are preferably provided, for instance, on the side and which may advantageously have bore diameters smaller than 0.1, 0.2 or 0.5 mm. The tube 202 may be closed at the end 204. A closed end 204 may additionally comprise bores 203′, e.g. configured axially, for the passage of process gas there through.

The apparatus 100 of FIG. 1 may be realized in the form of a carousel on which the containers 102 can be guided on a circular segment path whilst traveling through the plasma treatment area.

FIG. 2b shows another example of a gas lance 301 which is electrically conducting and, at the same time, capable of supplying a high frequency and a process gas. In this example, the gas lance 301 may be formed of a tube 302 made of a metallic foam, e.g. of an open-pored aluminum foam with a pore size <10-100 μm. The end 304 of the tube 302 may be closed or likewise be made of an open-pored metal foam. A closed end 304 may additionally include bores, e.g. configured axially, for the passage of process gas there through.

In another advantageous embodiment of a gas lance, the gas lance may include, for instance, a metallic core for the conduction of the high frequency, while the process gas can be supplied to the container outside the metallic core in an electrically insulating material.

FIG. 3a represents, for instance, a gas lance 401 which may include a massive metallic core 406 as solid material. The metallic core 406 may serve as an antenna for the high-frequency transmission. A double-tube 403 made, for instance, of a synthetic material or ceramics may be located around the metallic core 406. The two tubes 405, 404 of the double-tube 403 may by placed inside each other and be spaced apart from each other by 0.1-2 mm, preferably 0.5 mm. The outer tube 404 may be provided with bores 402, preferably on the side and preferably with bore diameters <0.5 mm allowing the process gas to flow out, preferably on the side, and be distributed uniformly in the container.

FIG. 3b represents by way of example another possible advantageous embodiment of a gas lance 501. A massive metallic core 505 may be enclosed by a capillary tube 503, which is made, for instance, of a ceramic material, which may include capillaries 504, preferably parallel to the gravity direction and with capillary diameters preferably between 0.1-0.5 mm, in particular preferably of 0.3 mm, and through which the process gas may be conducted. The capillary tube 503 may be provided with bores 502, preferably on the side and preferably with bore diameters smaller than the capillary diameters, e.g. <0.1 mm, which may communicate with the capillaries 504, allowing the process gas to flow out, preferably on the side, and be distributed uniformly in the container.

Further, it is conceivable that the gas lance is made of an electrically non-conducting core, which may, however, be gas-permeable for the supply of process gas. This electrically non-conducting core may then be cladded with an electrically conducting material.

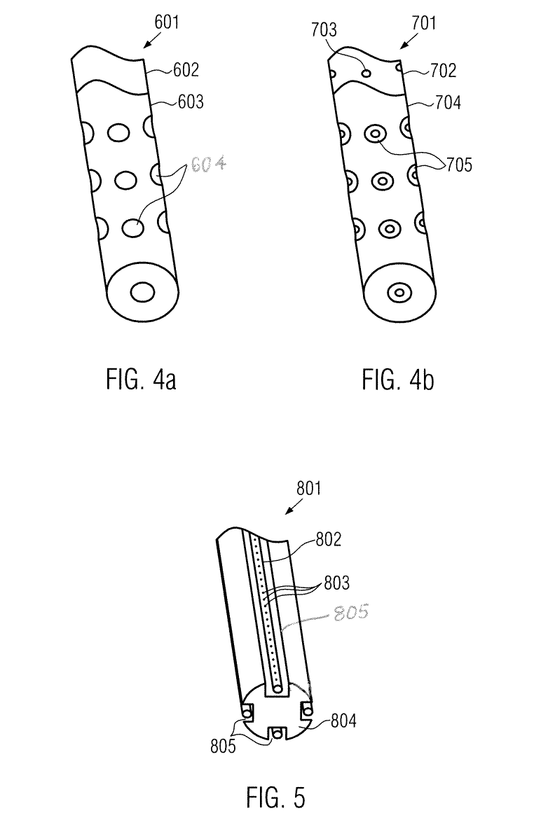

FIG. 4a represents by way of example a gas lance 601 whose core 602 may be an electrical insulator with a finely branched labyrinth-like channel system, such as a tube made of an open-pored ceramic foam with pore sizes of <10-100 μm. Said core 602 may have a metallic envelope 603. The metallic envelope 603 may be, for instance, a metallic tube with recesses 604 for the passage of process gas there through, a metallic foam with the same porosity as or a porosity different from the aforementioned core 602 made of a porous ceramic foam, or a vapor-deposited metallic enclosure with holes/recesses 604, or a metallic enclosure having a meshed structure, for the passage of process gas there through. The holes/recesses 604 may be of any shape, e.g. round, angular or oval, and have medium sizes in the range of 1 to 10 mm.

FIG. 4b shows by way of example a modification of the gas lance 601 of FIG. 4a, in which the gas lance 701 comprises a core 702 made of an electrically non-conducting material, e.g. ceramics, which may be realized in the form of a tube having, for instance, a plurality of bores 703, which are preferably arranged on the side, the bore diameters preferably being <0.5 mm. As was described in connection with FIG. 4a, the core 702 may comprise a metallic envelope 704. The metallic envelope 704 may be, for instance, a metallic tube with recesses 705 for the passage of process gas there through, a metallic foam or a vapor-deposited metallic enclosure with recesses, or a metallic enclosure having a meshed structure, for the passage of process gas there through. Analogous to the recesses 604 of the gas lance 601 the holes/recesses 705 may be of any shape, e.g. round, angular or oval, and have medium sizes in the range of 1 to 10 mm.

FIG. 5 represents by way of example a gas lance 801 whose solid material core may be formed by a massive electrically conducting material 804 with grooves 805 extending, for instance, on the side in the gravity direction. The grooves 805 may have a width and also a depth of 1 to 5 mm.

For instance, electrically non-conducting tubes or capillaries, e.g. ceramic capillaries 802, may be received in the grooves 805, which comprise bores 803 which are preferably arranged on the side and have bore diameters that are smaller than the capillary diameters, e.g. <0.1 mm. The process gas can then be supplied through these electrically non-conducting tubes or capillaries 802.

Another advantage of the gas lance embodiments described herein, which minimize hollow cathode discharges inside the gas lance, is, inter alia, that a partial conversion of process gas can already be suppressed or minimized inside the gas lance. Thus, undesired plasma-activated precipitations, e.g. siloxane fragments, at the gas inlet openings of the gas lance can be avoided or reduced. Such undesired precipitations and/or deposits can close the gas inlet openings in part or even entirely, so that the distribution of the process gas in the bottle may vary disadvantageously and result in an insufficient/deficient process gas supply, entailing a faulty and/or incomplete coating.

Furthermore, a harmful overheating of the gas lance caused by hollow cathode discharges and plasma formation inside the gas lance can be avoided by herein described advantageous embodiments of a gas lance, and the risk of overheating of the gas lance can be minimized.

No matter which one of the herein described exemplary modifications of a gas lance is used, which may be introduced into the interior of the container 102 to be treated, the contour of the gas lance may be adapted to the shape of the container. Thus, the uniformity of the coating of the container wall can advantageously be improved, as compared to a gas lance that is not adapted to the shape of the container.

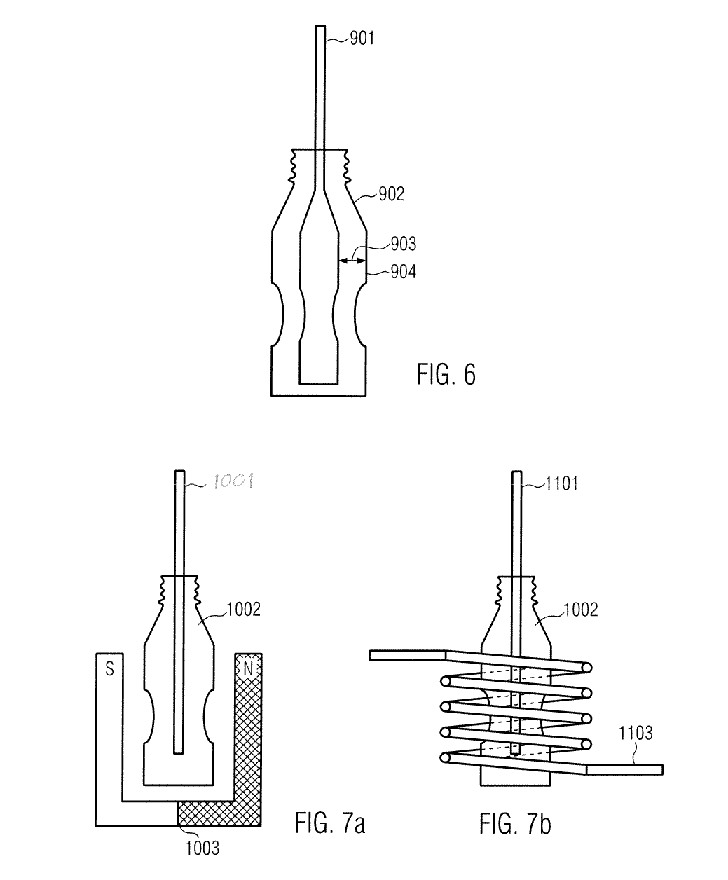

This is illustrated by way of example in FIG. 6, in which the contour of a gas lance 901 can be adapted to the inner contour of the container 902 such that the distance 903 between the gas lance and the container 904 is on average constant, except, for instance, for a tolerance in the constancy of the distance of less than 10, 20 or 60%.

Again, no matter which one of the exemplary gas lances and the container coating apparatus described above is used, a magnetic field can be additionally generated in the interior of the containers to be treated so as to be capable of additionally influencing the container coating process.

The magnetic field can be generated, for instance, by one or more permanent magnets or electric coils in most different orientations outside the containers. It is the goal to allow the generation of a high magnetic field strength inside a container to be treated. Mentioned magnetic field generating elements are situated as closely as possible on the outside on the container wall, e.g. with a distance <2, 5 or 10 mm from the outer wall of the container, so as to allow the generation of a magnetic field which is as strong as possible on the inner surface of the container.

Advantageously, the magnetic field has the effect that the plasma becomes more intensive as the electrons can be confined to a smaller space with respect to their direction of motion.

For homogenizing the effect the container may additionally be rotated during the treatment.

FIG. 7a shows by way of example that a magnetic field can be generated in the interior of the container 1002 to be treated by a permanent magnet 1003, and that in said container 1002 a gas lance 1001 may be located.

FIG. 7b shows by way of example that a magnetic field can also be generated in the interior of the container 1102 to be treated by a coil 1103, and that in said container 1102 a gas lance 1101 may be located.

1. An apparatus for coating a container by means of a plasma treatment, the apparatus comprising:
at least one high-frequency source, at least one outer electrode located outside a container to be treated, and at least one at least partially electrically conducting gas lance for the supply of process gas into the container (102), wherein the at least one outer electrode is grounded and/or is on the same potential as other parts of the container coating apparatus located outside the container to be treated, and the at least one gas lance is capable of irradiating a high frequency generated by a high-frequency source into the interior of the container to be treated.

2. An apparatus according to claim 1, wherein the gas lance is at least partially electrically shielded with an electrical coaxial shielding, and wherein the electrical coaxial shielding of the gas lance ends inside the container.

3. An apparatus according to claim 1, wherein the gas lance is is made of a material which is simultaneously electrically conducting and permeable to process gas.

4. An apparatus according to claim 1, wherein the gas lance is configured such that the supply of process gas and the conduction of the high frequency takes place physically separated, and wherein a part of the gas lance conducting the high frequency is electrically conducting and a part of the gas lance supplying the process gas is made at least in part of an electrically non-conducting material.

5. An apparatus according to claim 4, wherein the gas lance comprises a massive metallic core as solid material, wherein the metallic core is enclosed by a double-tube comprising an inner tube and an outer tube for the supply of process gas, which is made of a synthetic material, and the inner and outer tubes of the double-tube are placed inside each other and are spaced apart from each other by 0.1-2 mm, and the outer tube is provided with bores.

6. An apparatus according to claim 4, characterized in that the gas lance comprises a massive metallic core which is enclosed by a capillary tube for the supply of process gas, which is made of a ceramic material, and the capillary tube comprises capillaries and the capillary tube is provided with bores on the side and with bore diameters smaller than the capillary diameters which communicate with the capillaries.

7. An apparatus according to claim 4, wherein the gas lance comprises a core formed of an electrical insulator with a finely branched labyrinth-like channel system for the supply of process gas, and the core is enclosed by a metallic envelope including openings for the passage of process gas there through.

8. An apparatus according to claim 7, wherein the gas lance comprises a core made of an electrically non-conducting material for the supply of process gas, which is configured as a tube, and which comprises a plurality of bores arranged on the side and the core is enclosed by a metallic envelope, wherein the metallic envelope with openings therethrough for the passage of process gas there through.

9. An apparatus according to claim 4, wherein the gas lance comprises a solid material core made of an electrically conducting material, and the solid material core comprises grooves extending on the side in the gravity direction, and the grooves accommodate electrically non-conducting conduits for the supply of process gas, which comprise bores that are preferably arranged on the side and have bore diameters smaller than the capillary diameters.

10. An apparatus according to claim 1, wherein an outer contour of the gas lance is adapted to the inner contour of the container and a distance between the gas lance and the container is on average constant, except for a tolerance in the constancy of the distance of less than 60%.

11. An apparatus according to claim 1, wherein a magnetic field is generated inside the container by one or more permanent magnets or an electric coil outside of the container.

12. An apparatus according to claim 1, wherein the apparatus is configured such that the interior of the container can be evacuated to a first pressure range between 1 and 30 Pa, and that the region outside the container can be evacuated in part or in whole to a second pressure range different from that inside the container.

13. A method for the plasma-enhanced coating of a container, the method comprising:
supplying process gas to the container by an ungrounded gas lance;
supplying the container with a high frequency coupled to a grounded outer electrode located outside the container;
converting the process gas inside the container in whole or in part into a plasma; and
coating the interior of the container by means of a chemical vapor deposition.

14. An apparatus according to claim 1, wherein the container comprises a plastic bottle.

15. An apparatus according to claim 3, wherein the gas lance comprises a metallic tube having a plurality of gas inlet bores.

16. An apparatus according to claim 15, wherein the gas inlet bores have bore diameters smaller than 0.5 mm and bore lengths of 0.1 to 20 mm.

17. An apparatus according to claim 3, wherein the gas lance comprises a metallic tube of a porous metal foam.

18. An apparatus according to claim 17, wherein the metallic tube comprises a microporous foam of aluminum with average pore radii of 10 μm to 100 μm.

19. An apparatus according to claim 4, wherein the part of the gas lance supplying the process gas is further made in part of an electrically conducting material.

20. An apparatus according to claim 1, wherein the gas lance is configured such that the supply of process gas and the conduction of the high frequency takes place physically separated, and wherein a part of the gas lance conducting the high frequency is electrically conducting and a part of the gas lance supplying the process gas is made in whole of an electrically conducting material.

21. An apparatus according to claim 6, wherein the capillaries are arranged parallel to the gravity direction and have capillary diameters between 0.1 mm and 0.5 mm, and the bore diameters are less than 0.1 mm.

22. An apparatus according to claim 7, wherein the metallic envelope comprises a metallic tube with holes therethrough.

23. An apparatus according to claim 7, wherein the metallic envelope comprises a porous metallic foam.

24. An apparatus according to claim 7, wherein the metallic envelope comprises a vapor-deposited metallic enclosure with holes.

25. An apparatus according to claim 7, wherein the metallic envelope comprises a metallic mesh.

26. An apparatus according to claim 9, wherein the electrically non-conducting conduits comprise ceramic capillaries.

27. An apparatus according to claim 12, wherein the second pressure range is 100 Pa to 4000 Pa.
